(19) United States
(12) Patent Application Publication
(10) Pub. No.: US 2011/0163334 A1
(43) Pub. Date: Jul. 7, 2011

(54) COLOUR MIXING METHOD FOR CONSISTENT COLOUR QUALITY

(75) Inventors: Marcellinus P.C.M. Krijn, Eindhoven (NL); Ramon P. Van Gorkom, Eindhoven (NL); Michel C. J. M. Vissenberg, Roermond (NL); Oscar H. Willemsen, Den Bosch (NL)

(73) Assignee: KONINKLIJKE PHILIPS ELECTRONICS N.V., EINDHOVEN (NL)

(21) Appl. No.: 13/063,569

(22) PCT Filed: Sep. 11, 2009
(86) PCT No.: PCT/IB2009/053982

§ 371 Date: Mar. 11, 2011

(30) Foreign Application Priority Data
Sep. 16, 2008 (EP) 08164373.6

(51) Int. Cl. H01L 33/08

(52) U.S. Cl. 257/88; 257/E33.061; 257/E33.067

(57) ABSTRACT

The present invention relates to a light emitting device (100; 300; 400; 500) comprising at least two light emitting diodes (101; 301; 401; 501) and a first optical layer (102; 302; 402; 502) comprising a plurality of lenses (103; 303). The first optical layer (102; 302; 402; 502) is directly illuminated by the light emitting diodes (101; 301; 401; 501) and is adapted to create a plurality of images (104) of the light emitting diodes (101; 301; 401; 501). A device of the present invention provides an improved color quality in the far-field and is suitable for large area applications.

### TECHNICAL FIELD

The present invention relates to a light emitting device comprising at least two light emitting diodes and a first optical layer comprising a plurality of lenses. The first optical layer is directly illuminated by said light emitting diodes and is adapted to create a plurality of images of said light emitting diodes.

### BACKGROUND OF THE INVENTION

Luminaires based on light-emitting-diodes (LEDs) enable architects and interior designers to create an interior style according to their liking. By using several light sources, simple as well as complex light effects can be created, e.g. different kinds of color and dynamic effects. The use of colored lights enhances the beauty and atmosphere of interiors and exteriors.

Compared to traditional lighting, lighting systems based on LEDs have more degree of freedom with respect to color, form factor, directionality etc. and are thus more convenient in the creation of such light effects. LEDs are available in many different colors, they are small, and they are becoming very efficient.

Color variability can be achieved by combining LEDs that emit colored light of different colors, e.g. red, green and blue. An RGB LED (Red Green Blue LED), also referred to as a “full color” LED, can produce a vast array of colors, and when properly combined, could also produce white light. By means of some kind of collimating structure, directional light (e.g. a spot light) can be obtained.

However, conventional multi-colored LEDs including conventional RGB assemblies suffer from poor color mixing, especially in the far-field. Combining LEDs that emit different colors can give rise to colored shadows: for example, if one uses a solution where each LED has its own collimator, then each source will create its own shadow. Each shadow has a different color when it originates from a different color of light and this may result in a “rainbow” of colors.

US 2007/0268694 discloses a multicolor LED assembly which provides an improved and more uniform color mixture. The assembly includes at least one lens overlying an encapsulant which encapsulates a plurality of LED dies. The lens redirects light from each or the plurality of LED dies such that illuminance and luminous intensity distribution of the plurality of LED dies substantially overlap.

Although the assembly described in US 2007/0268694 results in an improved color mixing, this is achieved in a rather arbitrary way and is not well suited for large area applications. Furthermore, a plurality of LED dies packed closely together is required to ensure a good mixing of the light and to enhance the optical efficiency of the device. Accordingly, the LED spacing needs to be rather small in order to arrive at a uniform illumination.

Light emitting diodes are quite expensive and from an economic point of view it is desired to limit the amount of LEDs required in order to enable mass production. A consequence of decreasing the amount of LEDs in a device adapted for color mixing in large area applications is that if the LEDs emitting different colors are too far apart, it may result in a very colorful and not well mixed light distribution in the far field.

Accordingly, there is a need in the art to provide a light emitting device which guarantees a consistent and controllable color quality in the far-field, the device being less expensive to manufacture. Furthermore, there is a need for a light emitting device which is efficient, results in a uniform illumination and which is compact in order to enable an appealing form factor.

### SUMMARY OF THE INVENTION

One object of the present invention is to fulfill the above mentioned need and to provide a light emitting device which provides for a better mixing of colors in position and angular space and which overcomes the drawbacks described above.

This and other objects of the present invention are achieved by a light-emitting device according to the appended claims.

Thus, in a first aspect the present invention relates to a light emitting device comprising at least two light emitting diodes and a first optical layer comprising a plurality of lenses. The first optical layer is directly illuminated by the light emitting diodes and is arranged to project a plurality of images of the at least two light emitting diodes. The light emitting device further comprises a second optical layer being arranged at a distance (Lᵢ) from the first optical layer, wherein the distance (Lᵢ) corresponds to the distance from the first optical layer to where the projected image of a first one of the light emitting diodes coincides with the projected image of a second one of the light emitting diodes.

In a device of the present invention, only a few LEDs, being coarsely spaced are required to provide an efficient method to mix the light produced by the LEDs and to provide a consistent color quality and uniform illumination in the far-field.

Light emitted by each of the light emitting diodes contacts the first optical layer, which is directly illuminated by the light emitting diodes. The first optical layer comprises a plurality of lenses and these are adapted to project a plurality of images of the light emitting diodes; i.e. each light emitting diode is imaged by each of the lenses onto an image plane resulting in as many images as there are lenses.

Since only a limited number of light emitting diodes are required, less power and energy are needed to operate the light emitting device. Furthermore, this implies reduced manufacturing costs.

The second optical layer is arranged to receive light refracted by the first optical layer and the distance (Lᵢ), where the second optical layer is arranged corresponds to the distance from the first optical layer to where the projected image of a first one of the light emitting diodes coincides with the projected image of a second one of the light emitting diodes. The arrangement of a second optical layer at this distance provides for the best light mixing, light intensity and mixing of colors. Accordingly, an increased and more homogenous illumination may be obtained.

In embodiments, the second optical layer is a diffusive optical layer.

Accordingly, light refracted by the first optical layer will be diffused by the second optical layer resulting in a homogenous and diffuse illumination.

In alternative embodiments, the second optical layer comprises at least one wavelength converting material arranged to receive light refracted by the first optical layer and to convert it into light of a different wavelength.

Accordingly, the light emitting device of the invention is also applicable to color mixing when using LEDs in combination with remote wavelength converting material; i.e. phosphors emitting different colors.

In alternative embodiments, the second optical layer is divided into a plurality of separate domains. These separate domains may have different optical properties.

For example, at least one of the domains of the second optical layer may comprise a diffusive material. In contact with such domains, the light refracted from the first optical layer will be diffused homogenously. By adjusting the properties of these domains, the brightness and diffusion of the output light may be varied for different applications.

At least one of the domains may also comprise a wavelength converting material. The wavelength converting material absorbs light refracted by the first optical layer and converts it into light of a different wavelength. By adjusting the properties; i.e. by using different types of wavelength converting material in each of the domains or by shifting the arrangement of these domains, the color and color temperature may be varied.

When the domains of the second optical layer comprise an alternating pattern of diffusive particles and wavelength converting material, an improved light and color mixing can be achieved.

In order to prevent loss of light, the light emitting device according to the present invention may further comprise reflective side walls arranged to reflect light emitted by the light emitting diodes and/or refracted by the first optical layer. The reflective side walls reflect the light directed towards the first optical layer, upward to increase the amount of light emitted from the light emitting device.

In embodiments of the invention, the first optical layer and the second optical layer are arranged to be movable in a plane parallel to the first optical layer. This allows for the color and color temperature to be adjusted and varied for different applications.

In alternative embodiments, the first optical layer and the second optical layer are arranged to be movable in a direction along the normal to the first optical layer. Hence, the first and the second optical layer may be adjusted with respect to the location of the light emitting diodes. Hence, a device according to the present invention is flexible and may be easily adjusted for various applications.

These and other aspects of the invention will be apparent from and elucidated with reference to the embodiment(s) described hereinafter.

### BRIEF DESCRIPTION OF THE DRAWINGS

FIG. 1 schematically illustrates a first embodiment of a light emitting device according to the present invention.

FIG. 2 schematically illustrates a second optical layer according to the invention.

FIG. 3 illustrates a third embodiment of a light emitting device according to the present invention further comprising reflective side walls.

FIG. 4 illustrates an alternative embodiment of a light emitting device according to the present invention comprising curved reflective side walls.

FIG. 5 illustrates an alternative embodiment of a light emitting device according to the present invention.

### DETAILED DESCRIPTION OF THE INVENTION

The present invention relates to a light emitting device according to the appended claims.

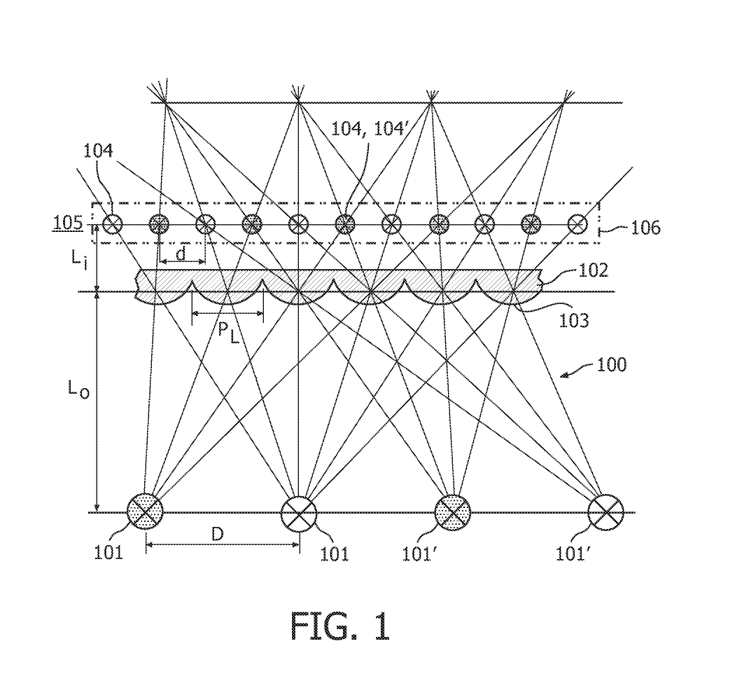

One embodiment of a light emitting device 100 according to the present invention is illustrated in FIG. 1. The light emitting device 100 comprises at least two light emitting diodes 101 and a first optical layer 102 comprising a plurality of lenses 103. The first optical layer 102 is directly illuminated by the light emitting diodes 101 and is arranged to project a plurality of images 104 of the at least two light emitting diodes 101. The device 100 further comprises a second optical layer 106 which is arranged at a distance (Lᵢ) from the first optical layer 102, wherein the distance (Lᵢ) corresponds to the distance from the first optical layer 102 to where the projected image 104 of a first one of the light emitting diodes 101 coincides with the projected image 104′ of a second one of the light emitting diodes 101′.

Light emitted by each of the light emitting diodes 101 contacts the first optical layer 102 which comprises a plurality of lenses 103. The lenses 103 are adapted to project a plurality of images 104 of the light emitting diodes 101; i.e. each light emitting diode 101 is imaged by each of the lenses 103 onto an image plane 105 resulting in as many images 104 as there are lenses 103.

Accordingly, only a few LEDs 101 are required to provide an efficient method to mix the light produced by the LEDs 101 and to provide a consistent color quality and uniform illumination in the far-field. Since only a limited number of LEDs 101 are required, less power and energy are needed to operate the light emitting device. Hence, manufacturing costs may be reduced.

The second optical layer 106 is arranged to receive light refracted by the first optical layer 102 and the distance (Lᵢ), where the second optical layer 106 is arranged corresponds to the distance from the first optical layer 102 to where the projected image 104 of a first one of the light emitting diodes 101 coincides with the projected image 104′ of a second one of the light emitting diodes 101′. The arrangement of a second optical layer at this distance provides for the best light mixing, light intensity and mixing of colors. Accordingly, an increased and more homogenous illumination may be obtained.

The light emitting diodes 101 are typically arranged at a distance D from each other, wherein D is equal to or larger than the diameter of each of the light emitting diodes 101. Typically, the distance D between one light emitting diode and another is >3 mm, e.g. in the range of from 3 mm to 50 mm, e.g. in the range of from 5 mm to 20 mm.

Hence, the distance between one light emitting diode 101 and another is relatively large and only a limited amount of coarsely spaced LEDs 101 are required as the lenses 103 of the first optical layer 102 are adapted to create many virtual images 104 of these LEDs 101, thereby generating a homogenous and improved color mixing.

As used herein, the term “diameter of the light emitting diode” means the smallest diameter that includes all the LED dies in the LED package.

LEDs are advantageously used due to their small size, potential energy savings and long life.

The first optical layer 102 is adapted to project a plurality of images 104, at a distance d from each other, of the light emitting diodes 101 onto an image plane 105. The distance d is typically in the range of from 0.05 mm to 10 mm, e.g. from 0.1 mm to 2 mm

The first optical layer 102 is arranged at a distance, L₀ from the light emitting diodes 101. Typically, L₀ is in the range of from 2 mm to 100 mm, e.g. in the range of from 30 mm to 70 mm.

When L₀ exceeds 100 mm, the lamp becomes too thick from an aesthetic point of view. In contrast, L₀ being less than 2 mm implies that the LEDs have to be very closely spaced for the method to work. This is not appreciated from an economic point of view since a large number of LEDs is required for the system to work.

Light emitted by the light emitting diodes 101 is received by the lenses 103 of the first optical layer 102. Preferably, the lenses 103 are lenticular lenses; i.e. lenses designed so that when viewed from slightly different angles, different images are magnified.

Typically, the lenses 103 have a contoured surface with a pitch length, P_{L} in the range of from 0.05 mm to 10 mm. Preferably, the pitch length, P_{L} is as small as possible as this results in the highest number of images 104 of the light emitting diodes 101. A higher number of images leads to a better homogeneity of the light distributed. Hence, the lenses preferably have a pitch length in the range of from 0.1 mm to 2 mm.

The contoured lenses 103 direct light from each of the LEDs 101 such that the luminous intensity distribution of the LEDs 101 substantially overlap. A controlled color mixing in the far-field and an improved optical efficiency is achieved by a device of the present invention. Accordingly, the system is well suited for large area applications.

In a light emitting device according to the present invention, the relationship between L₀, D, Lᵢ, P_{L} and d is typically d=((L₀+Lᵢ) P_{L}−D Lᵢ)/L₀.

When this relationship is obeyed, a more controlled mixing of colors in position and angular space is obtained. The angular distribution of the light in the image plane equals that in the object plane. Accordingly, a more consistent color quality in the far-field is achieved and the occurrence of colored shadows can be avoided. When the light emitting diodes 101 are of the same type, the images 104 will overlap.

If the light emitted by the light emitting diodes 101 has a Lambertian distribution, then also the light in the image plane 105 will have a Lambertian distribution (provided that the lenses are of good optical quality); i.e. the apparent brightness of the light to an observer is the same regardless of the observer's angle of view.

In embodiments, the second optical layer 106 is a diffusive optical layer. Hence, the second optical layer may comprise at least one diffusive material which may be diffusive particles of e.g. titanium dioxide. Alternatively, the diffusive optical layer may be a transparent layer with a roughened surface or a holographic diffuser. The degree of diffusivity may be varied for different applications.

Light refracted by the first optical layer 102 will be diffused by the second optical layer 106 resulting in a more homogenous and diffuse illumination.

Alternatively, the second optical layer 106 comprises at least one wavelength converting material.

As used herein the term “wavelength converting” refers to a material or an element that absorbs light of a first wavelength resulting in the emission of light of a second, longer wavelength. Upon absorption of light, electrons in the material become excited to a higher energy level. Upon relaxation back from the higher energy levels, the excess energy is released from the material in form of light having a longer wavelength than of that absorbed. Hence, the term relates to both fluorescent and phosphorescent wavelength conversion.

The wavelength converting material dispersed within the second optical layer 106 is arranged to receive light refracted by the first optical layer 102 and to convert it into light of a different wavelength. The second optical layer 106 may comprise one type of wavelength converting material or different types of wavelength converting materials or, alternatively, a combination of diffusive material and wavelength converting material.

Accordingly, the light emitting device of the invention is also applicable to color mixing when using LEDs in combination with remote wavelength converting material; i.e. phosphors emitting different colors.

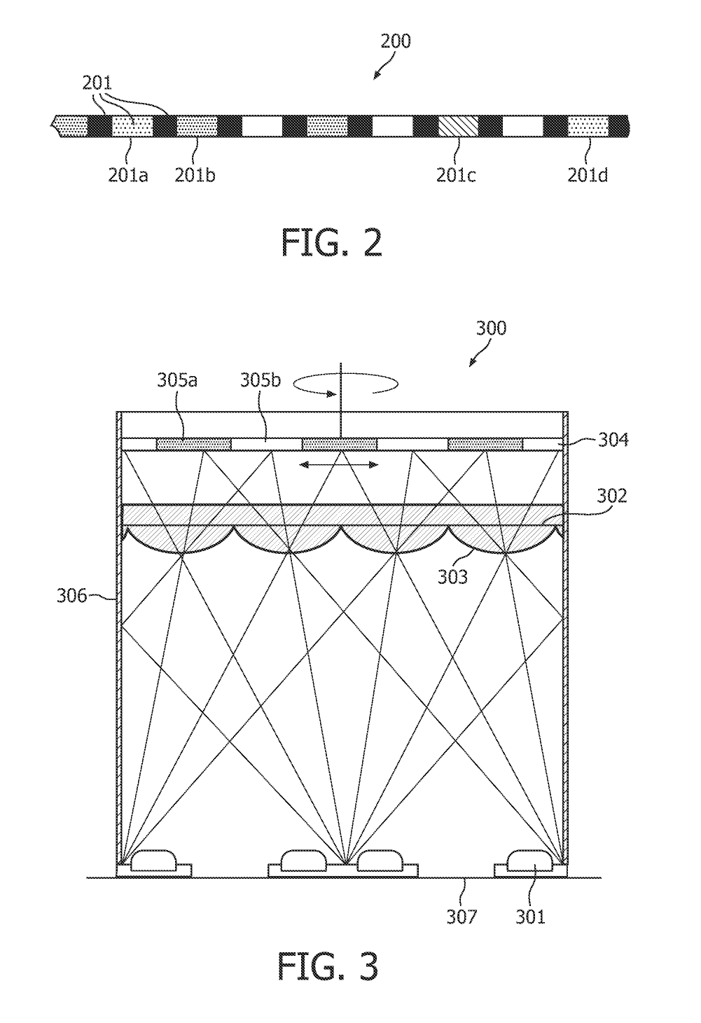

In embodiments of the invention, illustrated in FIG. 2, the second optical layer 200 is divided into separate domains 201.

These separate domains 201 may have different optical properties.

For example, at least one of the domains 201 of the second optical layer 200 may comprise a diffusive material. Such domains may be referred to as “diffusive domains”, denoted 201a in FIG. 2 and function to diffuse at least part of the light refracted from the first optical layer homogenously.

At least one of the domains 201 may also comprise a wavelength converting material. Such domains may be referred to as “wavelength converting domains”, denoted 201b in FIG. 3 and function to absorb at least part of the light refracted by the first optical layer and to convert it into light of a different wavelength.

Preferably, the second optical layer 200 is divided into separate domains 201, comprising either wavelength converting material or diffusive material. This allows for the light refracted by the first optical layer to become perfectly mixed in position and the light mixing in the angular domain is further improved.

For example, if the domains of wavelength converting material 201b comprise a yellow phosphor and blue light emitting diodes are used, the light emitted will be converted into yellow light when imaged onto the yellow phosphor domains. This light together with the remainder of blue light that is not converted will result in white light with good uniformity.

One problem with the use of yellow phosphors is that when the device is switched off, it may have a yellow appearance which is not appreciated. To get rid of this yellow appearance in the off-state, the second optical layer 200 may further comprise domains of an opaque material having a blue color. These blue colored domains are denoted 201c in FIG. 3 and may be interspersed between the wavelength converting domains 201b (and the diffusive domains 201a if these are present).

The blue colored domains 201c prevent a yellow appearance in the off-state since the yellow together with the blue result in a white appearance of the light emitting device in the off-state. In the on-state, the device will still be efficient since the first optical layer will ensure that no light is imaged onto the blue domains of paint; i.e. the images of the LEDs are located in the wavelength converting domains 201b and in between these images there is blue paint. Accordingly, the yellow appearance in the off-state is avoided and no significant light is lost in the on-state.

In alternative embodiments of the invention, the second optical layer 200 comprises light guidance domains 201d.

As used herein, the term “light guidance domain” means a domain which is opaque for light; i.e. a domain which absorbs light. This may e.g. be black paint.

In case the lenses of the first optical layer are non-ideal, the light guidance domains 201d can act as “guard bands” and ensure that the light of each type of LEDs is landing on the correct domain of wavelength converting material 201b or diffusive material 201a. The light guidance domains 201d may prevent the occurrence of image overlap which may take place if the lenses are non-ideal. If the lenses are non-ideal, the image of an LED in the second optical layer will be larger than intended and may start to overlap with neighboring images of other LEDs.

In embodiments of the invention, the lenses of the first optical layer direct light from the light emitting diodes to the domains comprising diffusive particles 201a or those comprising wavelength converting material 201b. By tuning the relative strength of the different types of LEDs, the color temperature can be tuned.

The properties of the second optical layer 200 may be adjusted by adjusting the different types of domains 201. Hence, the brightness and color output may be varied for different applications.

Referring now to FIG. 3, a light emitting device 300 comprising at least two light emitting diodes 301, a first optical layer 302 comprising a plurality of lenses 303 and a second optical layer 304 divided into separate domains 305a and 305b is illustrated. The light emitting device 300 of the invention may further comprise reflective side walls 306 arranged to reflect light emitted by the light emitting diodes 301 and/or refracted by the first optical layer 302.

The arrangement of LEDs 301 is surrounded by these reflective side walls 306, which prevent loss of light and further create many virtual sources as the light is reflected thereon.

The light emitting diodes 301 may be any type of LED and the domains 305a and 305b may comprise different types of wavelength converting material. For example, blue LEDs may be used, wherein the light of these blue LEDs is converted by the domains 305a and 305b into light of different colors.

To achieve the best result and in order to image light emitting diodes 301 of different colors onto the same locations, the second optical layer 304 is arranged at a distance (Lᵢ) from the first optical layer 302 where the projected image of a first one of the LEDs coincides with the projected image of a second one of the LEDs, i.e. at or close to the image plane.

In this manner, in the image plane, a multitude of closely spaced light emitting diodes of different colors are created in an alternating fashion. By tuning the relative strength of the LEDs 301, the color emitted from the image plane can be tuned. The light produced in the image plane will be much more uniform in position and angular space than the light produced in the plane of the light emitting diodes 301.

Typically, Lᵢ is in the range of from 0.1 mm to 10 mm, preferably of from 0.5 mm to 5 mm.

Alternatively, the domains 305a and 305b may comprise a cool white phosphor and a warm white phosphor. Different types of blue light emitting diodes may be used as the light emitting diodes 301, and these are imaged onto the different types of phosphors. Accordingly, both types of phosphors produce white light, but with a different color temperature.

By tuning the relative strength of the blue LEDs 301, the light leaving the image plane and the second optical layer 304 can be tuned between cool white and warm white.

In preferred embodiments of the present invention, the first optical layer 302 and the second optical layer 304 are arranged to be movable in a plane parallel to the first optical layer 302.

As is illustrated by the arrows in FIG. 3 it is thus possible to slightly shift or rotate the arrangement of domains comprising wavelength converting material or diffusive material 305 with respect to the first optical layer 302. Accordingly, the brightness and light output may be adjusted for different applications.

By adapting the location of the first optical layer 302 and the second optical layer 304, the color and color temperature can be adjusted and varied for different applications.

In alternative embodiments, the first optical layer 302 and the second optical layer 304 are arranged to be movable in a direction along the normal to the first optical layer 302. Hence, the first and the second optical layer may be adjusted with respect to the location of the light emitting diodes 301. Accordingly, a device according to the present invention is flexible and may be easily adjusted for various applications.

As mentioned hereinbefore, only a limited amount of LEDs 301 are required since the lenses 303 of the first optical layer 302 create virtual images of the LEDs 301.

In embodiments, the light emitting device 300 further comprises a substrate 307 onto which the light emitting diodes 301 are arranged. Such a substrate 307 may comprise a reflective material such that light reflected in a backward direction; i.e. towards the LEDs 301 is reflected back towards the first optical layer 302. The light output is thereby further increased.

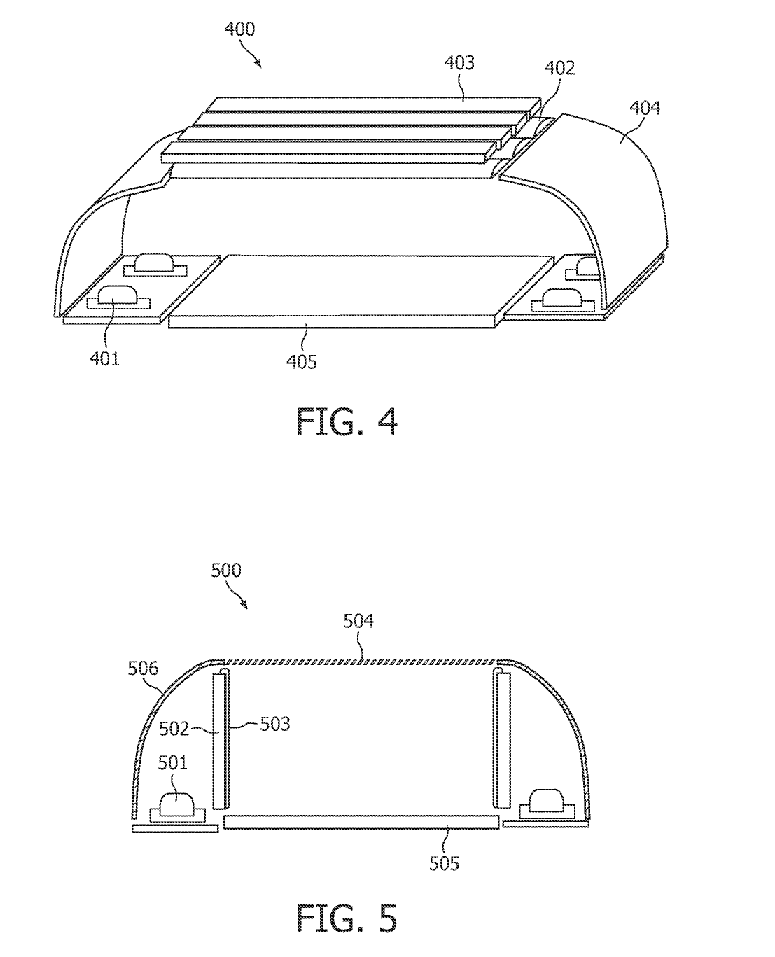

The reflective side walls 306 may have a planar configuration or a curved configuration. An example of a curved configuration is illustrated in FIG. 4.

In FIG. 4, the light emitting device 400 comprises a linear array of a limited number of LEDs 401, a first optical layer 402 and a second optical layer 403 as well as curved reflective side walls 404. The device 400 may also comprise a transparent light redirection layer 405 which redirects light by reflecting some light having the wrong angles and transmitting most of it. Furthermore, a reflective layer (not shown) may be placed on top of the second optical layer 403. In this figure, light is emitted in the downward direction; i.e. from the redirection layer 405.

By means of the curved reflective side walls 404, light emitted by the LEDs 401 is directed towards the first optical layer 402. The first optical layer 402 comprises a plurality of lenses and these are adapted to create a plurality of images of the LEDs 401. Where the projected image of a first one of the light emitting diodes coincides with the projected image of a second one of the light emitting diodes, i.e. at a distance (Lᵢ) from the first optical layer, a second optical layer 403 is arranged. The second optical layer 403 may comprise a plurality of wavelength converting domains or a combination of diffusive domains and wavelength converting domains. In this embodiment, light is reflected in a backwards direction; i.e. after the light is mixed by the combination of the first optical layer 402 and the second optical layer 403 located in the image plane of the lenses of the first optical layer 402, the light is directed downwards again, travelling through the first optical layer for a second time towards the transparent light redirection layer 405. This is either achieved by placing a reflective layer on top or by making the domains thick enough to reflect most of the light.

The light redirection layer 405 functions to confine the light emitted by the LEDs 401 to a cone of typically 60° in order to fulfill the glare norm for office lighting.

FIG. 5 illustrates an alternative embodiment of a light emitting device 500 according to the present invention, wherein the first optical layer 502 and the second optical layer 503 have a different arrangement. The device comprises a reflective layer 504 and a light redirection layer 505, wherefrom the light is emitted.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. For example, the present invention is not limited to the use of a specific type of light emitting diode, wavelength converting material, reflective material or diffusive material. Any type of LED with any color or wavelength combination may be used.

1. A light emitting device comprising at least two light emitting diodes and a first optical layer comprising a plurality of lenses; said first optical layer being directly illuminated by said light emitting diodes and being arranged to project a plurality of images of said at least two light emitting diodes; said light emitting device further comprising a second optical layer being arranged at a distance from said first optical layer, wherein said distance corresponds to the distance from said first optical layer to where the projected image of a first one of said light emitting diodes coincides with the projected image of a second one of said light emitting diodes.

2. A light emitting device according to claim 1, wherein said second optical layer is a diffusive optical layer.

3. A light emitting device according to claim 1, wherein said second optical layer comprises at least one wavelength converting material arranged to receive light refracted by said first optical layer and to convert it into light of a different wavelength.

4. A light emitting device according to claim 1, wherein said second optical layer is divided into separate domains.

5. A light emitting device according to claim 4, wherein at least one of said domains comprises a diffusive material.

6. A light emitting device according to claim 4, wherein at least one of said domains comprises a wavelength converting material.

7. A light emitting device according to claim 1, further comprising reflective side walls arranged to reflect light emitted by said light emitting diodes and/or refracted by said first optical layer.

8. A light emitting device according to claim 1, wherein said first optical layer and said second optical layer are arranged to be movable in a plane parallel to said first optical layer.

9. A light emitting device according to claim 1, wherein said first optical layer and said second optical layer are arranged to be movable in a direction along the normal to said first optical layer.
